(19) United States
(12) Patent Application Publication
(10) Pub. No.: US 2025/0284214 A1
(43) Pub. Date: Sep. 11, 2025

(54) LITHOGRAPHY SYSTEM AND METHODS

(71) Applicant: Taiwan Semiconductor Manufacturing Co., Ltd., Hsinchu (TW)

(72) Inventors: Shang-Chieh CHIEN, Hsinchu (TW); Chin-Hsiang LIN, Hsinchu (TW); Chin-Kun WANG, Hsinchu (TW); Li-Jui CHEN, Hsinchu (TW); Cheng Hung TSAI, Hsinchu (TW); Jyun-Yan CHUANG, Hsinchu (TW)

(21) Appl. No.: 18/597,549

(22) Filed: Mar. 6, 2024

(51) Int. Cl. G03F 7/00; G03F 1/22; G03F 1/62

(52) U.S. Cl. CPC G03F 7/70983; G03F 7/70841; G03F 7/70858; G03F 7/70933; G03F 1/22; G03F 1/62

(57) ABSTRACT

A method includes: depositing a mask layer over a substrate; protecting a mask of a mask assembly by a pellicle attached to a pellicle assembly, the pellicle and the pellicle assembly being laterally offset from the mask assembly by a distance; directing first radiation toward the mask with the pellicle positioned overlapping the mask; and exposing the mask layer of a semiconductor wafer by second radiation carrying a pattern of the mask

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A and 1B are views of portions of a lithography scanner according to embodiments of the present disclosure.

FIGS. 2A-2C are views illustrating effects of particles on a mask according to various aspects of the present disclosure.

FIGS. 3A and 3B are views illustrating use of a pellicle in accordance with various embodiments.

FIGS. 4A-4C are views illustrating a system including a pellicle and mask in accordance with various embodiments.

FIGS. 5 and 6 are views illustrating methods of fabricating a device according to various aspects of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Terms such as “about,” “roughly,” “substantially,” and the like may be used herein for ease of description. A person having ordinary skill in the art will be able to understand and derive meanings for such terms.

The present disclosure is generally related to lithography equipment for fabricating semiconductor devices, and more particularly to a pellicle-less frame that is part of a mask assembly. Dimension scaling (down) is increasingly difficult in advanced technology nodes. Lithography techniques employ ever shorter exposure wavelengths, including deep ultraviolet (DUV; about 193-248 nanometers), extreme ultraviolet (EUV; about 10-100 nanometers; particularly 13.5 nanometers), and X-ray (about 0.01-10 nanometers) to ensure accurate patterning at the scaled-down dimensions. In an EUV scanner, EUV light is generated by a light source, and reflected toward a wafer by multiple mirrors and a reflective mask. Only a fraction of the EUV light reaches the wafer, such that increasing intensity of EUV light generated by the light source is a topic of much interest.

The EUV scanner includes a mask assembly for shaping and reflecting light from a light source that is incident on the mask assembly. Elimination of particle sources inside a scanner chamber is beneficial to improving yield by avoid defects that arise from particles attaching to a mask of the mask assembly. However, even with significant progress on particle reduction, a pellicle that protects the mask from particles continues to be used in manufacture of some devices.

When a pellicle is employed, the pellicle is directly mounted as a film in front of the mask. In previous technology generations, ArF- and KrF-type pellicles could be manufactured to thickness of about 1 um, which provided strong reliability, because light transmission through material of the pellicle could reach about 99%. However, EUV light used in current and next generation technologies is very easily absorbed by any material. As such, the film thickness for a pellicle used in an EUV scanner is about 80 nm, and reliability is a concern as ruptures are common under very fast motion during scanning exposure. The pellicle is directly mounted in front of the mask. However, the very thin pellicle film mounted on the mask sustains scanning motion that may exceed 20G during exposure. Such a heavy acceleration speed is very challenging for pellicle reliability. Increasing thickness of the pellicle is one possibility, but negatively impacts EUV productivity.

In embodiments of this disclosure, a novel mechanical assembly is included in a scanner to achieve a “stand-alone” pellicle. The pellicle is not directly mounted on the EUV mask but can still be used to protect the mask from particles. In the embodiments, the pellicle film is separated from the mask to have non-synchronized movement, so as to escape the heavy acceleration speed during scanner exposure process, which increases sustainability during usage. In some embodiments, the pellicle is mounted on the mask but not completely fixed, thereby providing some tolerance during high-speed motion for more sustainability. The film size of the pellicle may be 1 cm×10 cm to 30 cm×30 cm. The pellicle having a larger size of film and the non-synchronized movement mechanical device may be used for shifting, rotating or performing other motion changes to expand applications, such as if the film suffers damage from particle sources or for enhancing protection of selected areas of the mask.

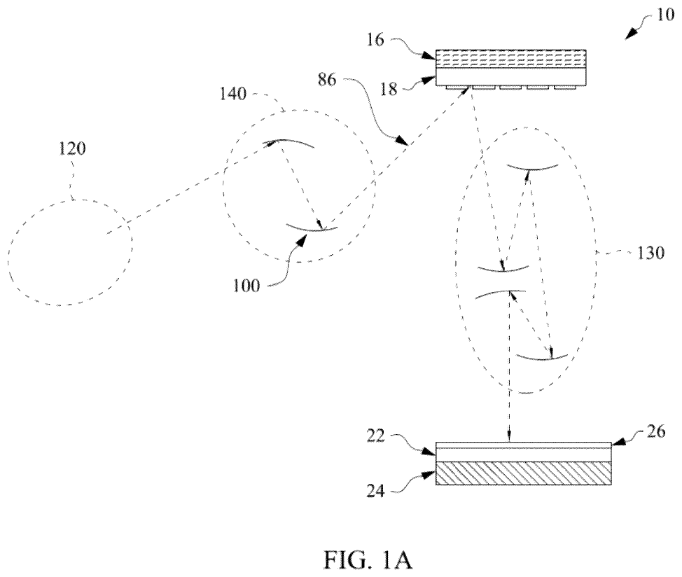

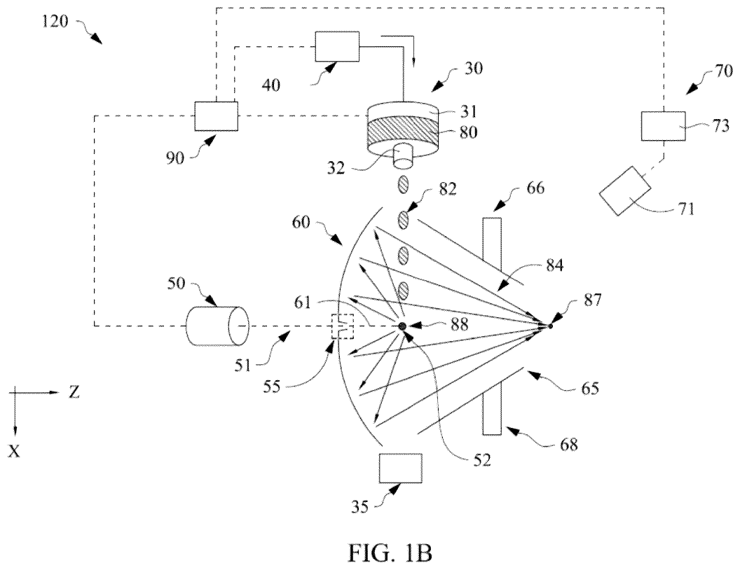

FIG. 1A is a diagrammatic schematic view of a lithography exposure system 10, in accordance with some embodiments. Description of the lithography system 10 is given in broad terms to provide context for understanding the embodiments of the present disclosure. In some embodiments, the lithography exposure system 10 is an extreme ultraviolet (EUV) lithography system designed to expose a resist layer by EUV radiation and may also be referred to as the EUV system 10. The EUV system 10 may also be referred to as an EUV scanner or lithography scanner. The lithography exposure system 10 includes a light source 120, an illuminator 140, a mask stage 16, a projection optics module (or projection optics box (POB)) 130 and a substrate stage 24, in accordance with some embodiments. The elements of the lithography exposure system 10 can be added to or omitted, and the disclosure should not be limited by the embodiment.

The light source 120 is configured to generate light radiation having a wavelength ranging between about 1 nm and about 100 nm in certain embodiments. In one particular example, the light source 120 generates an EUV radiation with a wavelength centered at about 13.5 nm. Accordingly, the light source 120 is also referred to as an EUV radiation source. However, it should be appreciated that the light source 120 should not be limited to emitting EUV radiation. The light source 120 can be utilized to perform any high-intensity photon emission from excited target fuel.

In various embodiments, the illuminator 140 includes various refractive optic components, such as a single lens or a lens system having multiple reflectors 100, for example lenses (zone plates) or alternatively reflective optics (for EUV lithography exposure system), such as a single mirror or a mirror system having multiple mirrors in order to direct light 86 from the light source 120 onto the mask stage 16, particularly to a mask 18 secured on the mask stage 16. In embodiments in which the light source 120 generates light in the EUV wavelength range, reflective optics and/or lenses are employed. In some embodiments, the illuminator 140 includes at least two lenses, at least three lenses, or more.

The mask stage 16 is configured to secure the mask 18. In some embodiments, the mask stage 16 includes an electrostatic chuck (e-chuck) to secure the mask 18. One reason an e-chuck is beneficial is that gas molecules absorb EUV radiation and the e-chuck is operable in the lithography exposure system for the EUV lithography patterning that is maintained in a vacuum environment to avoid EUV intensity loss. In the present disclosure, the terms mask, photomask, and reticle are used interchangeably. In the present embodiment, the mask 18 is a reflective mask. One exemplary structure of the mask 18 includes a substrate with a suitable material, such as a low thermal expansion material (LTEM) or fused quartz. In various examples, the LTEM includes TiO₂ doped SiO₂, or other suitable materials with low thermal expansion. The mask 18 includes a reflective multilayer deposited on the substrate. The mask stage 16 is operable to translate in two horizontal directions, such as an X-axis direction and a Y-axis direction, so as to expose multiple different regions of the semiconductor wafer 22 to light having a pattern generated by the mask 18. The semiconductor wafer 22 may have a mask layer 26 thereon, which may be a photoresist layer that is sensitive to the light carrying the pattern of the mask 18.

The projection optics module (or projection optics box (POB)) 130 is configured for imaging the pattern of the mask 18 on to a semiconductor wafer 22 secured on the substrate stage 24 of the lithography exposure system 10. In some embodiments, the POB 130 has refractive optics (such as for a UV lithography exposure system) or alternatively reflective optics (such as for an EUV lithography exposure system) in various embodiments. The light directed from the mask 18, carrying the image of the pattern defined on the mask, is collected by the POB 130. The illuminator 140 and the POB 130 are collectively referred to as an optical module of the lithography exposure system 10. In some embodiments, the POB 130 includes at least six reflective optics.

In some embodiments, the semiconductor wafer 22 may be made of silicon or other semiconductor materials. Alternatively or additionally, the semiconductor wafer 22 may include other elementary semiconductor materials such as germanium (Ge). In some embodiments, the semiconductor wafer 22 is made of a compound semiconductor such as silicon carbide (SiC), gallium arsenic (GaAs), indium arsenide (InAs), or indium phosphide (InP). In some embodiments, the semiconductor wafer 22 is made of an alloy semiconductor such as silicon germanium (SiGe), silicon germanium carbide (SiGeC), gallium arsenic phosphide (GaAsP), or gallium indium phosphide (GaInP). In some other embodiments, the semiconductor wafer 22 may be a silicon-on-insulator (SOI) or a germanium-on-insulator (GOI) substrate.

In addition, the semiconductor wafer 22 may have various device elements. Examples of device elements that are formed in the semiconductor wafer 22 include transistors (e.g., metal oxide semiconductor field effect transistors (MOSFET), complementary metal oxide semiconductor (CMOS) transistors, bipolar junction transistors (BJT), high voltage transistors, high-frequency transistors, p-channel and/or n-channel field-effect transistors (PFETs/NFETs), nanostructure field-effect transistors, and the like), diodes, and/or other applicable elements. Various processes are performed to form the device elements, such as deposition, etching, implantation, photolithography, annealing and/or other suitable processes. In some embodiments, the semiconductor wafer 22 is coated with a resist layer sensitive to the EUV radiation. Various components including those described above are integrated together and are operable to perform lithography processes.

The lithography exposure system 10 may further include other modules or be integrated with (or be coupled with) other modules, such as a cleaning module designed to provide hydrogen gas to the light source 120. The hydrogen gas helps reduce contamination in the light source 120. Further description of the light source 120 is provided with reference to FIG. 1B.

In FIG. 1B, the light source 120 is shown in a diagrammatical view, in accordance with some embodiments. In some embodiments, the light source 120 employs a dual-pulse laser produced plasma (LPP) mechanism to generate plasma 88 and further generate EUV radiation from the plasma. The light source 120 includes a droplet generator 30, a droplet receptacle 35, a laser generator 50, a laser produced plasma (LPP) collector 60, a monitoring device 70 and a controller 90. Some or all of the above-mentioned elements of the light source 120 may be held under vacuum. It should be appreciated that the elements of the light source 120 can be added to or omitted and should not be limited by the embodiment.

The droplet generator 30 is configured to generate a plurality of droplets 82, which may be elongated, of a target fuel 80 to a zone of excitation at which at least one laser pulse 51 from the laser generator 50 hits the droplets 82 along an X-axis, as shown in FIG. 1B. In an embodiment, the target fuel 80 includes tin (Sn). In an embodiment, the droplets 82 may be formed with an elliptical shape. In an embodiment, the droplets 82 are generated at a rate of about 50 kilohertz (kHz) and are introduced into the zone of excitation in the light source 120 at a speed of about 70 meters per second (m/s). Other material can also be used for the target fuel 80, for example, a tin containing liquid material such as eutectic alloy containing tin, lithium (Li), and xenon (Xe). The target fuel 80 in the droplet generator 30 may be in a liquid phase.

The laser generator 50 is configured to generate at least one laser pulse to allow the conversion of the droplets 82 into plasma 88. In some embodiments, the laser generator 50 is configured to produce a laser pulse 51 to the lighting point 52 to convert the droplets 82 to plasma 88 which generates EUV radiation 84. The laser pulse 51 is directed through window (or lens) 55 and irradiates droplets 82 at the lighting point 52. The window 55 is formed in the collector 60 and adopts a suitable material substantially transparent to the laser pulse 51. The droplet receptacle 35 catches and collects unused droplets 82 and/or scattered material of the droplets 82 resulting from the laser pulse 51 striking the droplets 82.

The plasma emits EUV radiation 84, which is collected by the collector 60. The collector 60 further reflects and focuses the EUV radiation 84 for the lithography processes performed through an exposure tool. In some embodiments, the collector 60 has an optical axis 61 which is parallel to the Z-axis and perpendicular to the X-axis. The collector 60 may include a single section, as shown, or at least two sections that are offset from each other in the z-axis direction. The collector 60 may further include a vessel wall 65 having first and second pumps 66, 68 attached thereto. In some embodiments, the first and second pumps 66, 68 include scrubbers configured to remove particulates and/or gases from the collector 60. The first and second pumps 66, 68 may be collectively referred to as “the pumps 66, 68” herein.

In an embodiment, the laser generator 50 is a carbon dioxide (CO2) laser source. In some embodiments, the laser generator 50 is used to generate the laser pulse 51 with single wavelength. The laser pulse 51 is transmitted through an optic assembly for focusing and determining incident angle of the laser pulse 51. In some embodiments, the laser pulse 51 has a spot size of about 200-300 μm, such as 225 μm. The laser pulse 51 is generated to have certain driving power to meet wafer production targets, such as a throughput of 125 wafers per hour (WPH). For example, the laser pulse 51 is equipped with about 23 KW driving power. In various embodiments, the driving power of the laser pulse 51 is at least 20 kW, such as 27 kW.

The monitoring device 70 is configured to monitor one or more conditions in the light source 120 so as to produce data for controlling configurable parameters of the light source 120. In some embodiments, the monitoring device 70 includes a metrology tool 71 and an analyzer 73. In cases where the metrology tool 71 is configured to monitor condition of the droplets 82 supplied by the droplet generator 30, the metrology tool may include an image sensor, such as a charge coupled device (CCD), complementary metal oxide semiconductor sensor (CMOS) sensor or the like. The metrology tool 71 produces a monitoring image including image or video of the droplets 82 and transmits the monitoring image to the analyzer 73. In cases where the metrology tool 71 is configured to detect energy or intensity of the EUV light 84 produced by the droplet 82 in the light source 12, the meteorology tool 71 may include a number of energy sensors. The energy sensors may be any suitable sensors that are able to observe and measure energy of electromagnetic radiation in the ultraviolet region.

The analyzer 73 is configured to analyze signals produced by the metrology tool 71 and outputs a detection signal to the controller 90 according to an analyzing result. For example, the analyzer 73 includes an image analyzer. The analyzer 73 receives the data associated with the images transmitted from the metrology tool 71 and performs an image analysis process on the images of the droplets 82 in the excitation zone. Afterwards, the analyzer 73 sends data related to the analysis to the controller 90. The analysis may include a flow path error or a position error.

In some embodiments, two or more metrology tools 71 are used to monitor different conditions of the light source 120. One is configured to monitor condition of the droplets 82 supplied by the droplet generator 30, and the other is configured to detect energy or intensity of the EUV light 84 produced by the droplet 82 in the light source 120. In some embodiments, the metrology tool 71 is a final focus module (FFM) and positioned in the laser source 50 to detect light reflected from the droplet 82.

The controller 90 is configured to control one or more elements of the light source 120. In some embodiments, the controller 90 is configured to drive the droplet generator 30 to generate the droplets 82. In addition, the controller 90 is configured to drive the laser generator 50 to fire the laser pulse 51. The generation of the laser pulse 51 may be controlled to be associated with the generation of droplets 82 by the controller 90 so as to make the laser pulse 51 hit each target 82 in sequence.

In some embodiments, the droplet generator 30 includes a reservoir 31 and a nozzle assembly 32. The reservoir 31 is configured for holding the target material 80. In some embodiments, one gas line is connected to the reservoir 31 for introducing pumping gas, such as argon, from a gas source 40 into the reservoir 31. By controlling the gas flow in the gas line, the pressure in the reservoir 31 can be manipulated. For example, when gas is continuously supplied into the reservoir 31 via the gas line, the pressure in the reservoir 31 increases. As a result, the target material 80 in the reservoir 31 can be forced out of the reservoir 31 in the form of droplets 82.

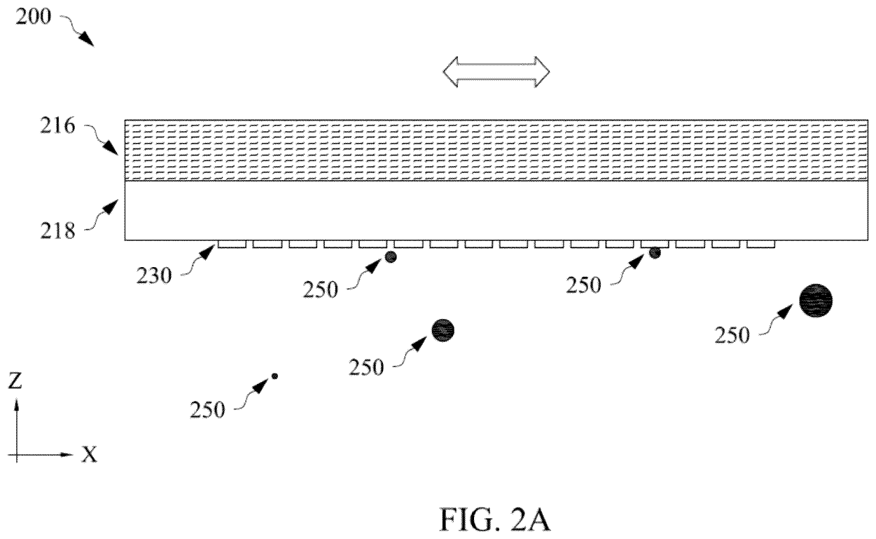

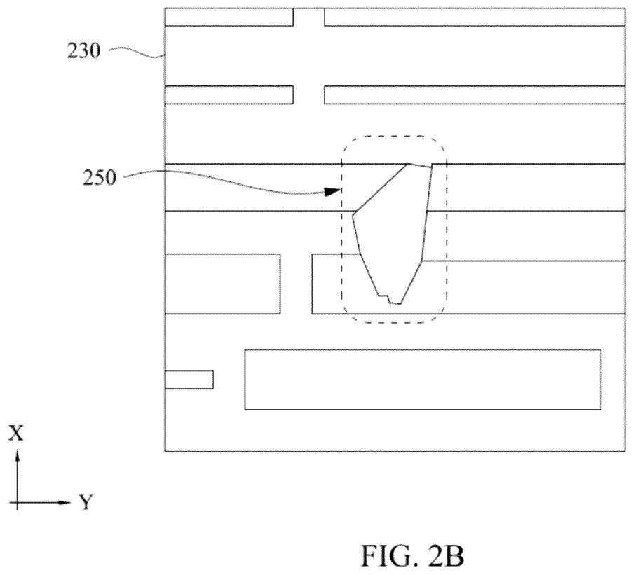

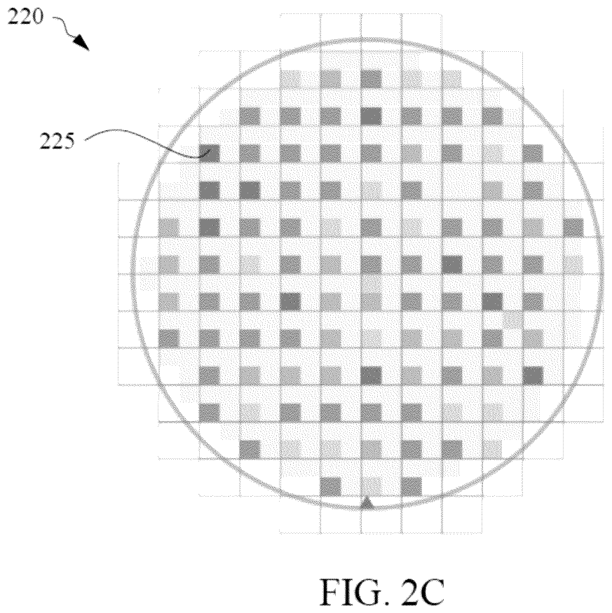

FIGS. 2A-2C are views depicting a mask assembly 200 of a lithography scanner, such as the lithography system 10, and particles 250 according to various aspects of the present disclosure. FIG. 2A is a side view of a mask assembly 200. FIG. 2B is a top view of a mask pattern 230 of the mask assembly 200. FIG. 2C is a diagram illustrating exposure errors in regions 225 of a semiconductor wafer 220 due to particles 250.

In FIG. 2A, the mask assembly 200 includes a mask stage 216 and a mask 218 attached thereto. The mask stage 216 and the mask 218 may be the mask stage 16 and the mask 18, respectively, of FIGS. 1A and 1B. The mask 218 includes mask patterns 230 that may be located in a layer of the mask 218 facing reflectors of the illuminator 140 and the POB 130 on either side of the mask assembly 200.

Particles 250 may be present in the lithography scanner. The particles 250 may include different types of particles generated by different sources in the lithography scanner. For example, the particles 250 may include tin particles generated by the light source 120 during formation of the plasma 88. The particles 250 may include SiC particles generated by movement of the mask assembly 200 in the X- and Y-axis directions. The particles 250 may include carbon particles generated by a pod or carrier used for transporting the mask 218 in and out of the lithography scanner. Other particles 250 having different material composition may be generated by other sources internal or external to the lithography scanner. One or more of the particles 250 may settle on the surface of the mask 218 on one or more mask pattern regions of the mask patterns 230.

FIG. 2B shows a view of the mask patterns 230 with a particle 250 thereon. The mask patterns 230 are exposed to the internal environment of the lithography scanner. While the mask assembly 200 is in the lithography scanner, the particle 250 may fall or settle on the mask 218. It should be understood that “fall” and “settle” include the meaning that a particle drifts toward the mask 218, makes contact therewith and attaches thereto, regardless of orientation of the mask 218 in three-dimensional space relative to the direction of gravity. The particle 250 may form a short circuit or bridge or merger between one or more pattern regions of the mask patterns 230. When the pattern of the mask 218 is transferred to a semiconductor wafer, an electrical defect, such as a short circuit or bridge or merger, may occur between features of the semiconductor wafer. For example, neighboring semiconductor fins or neighboring conductive traces may merge unintentionally, which may result in failure of an integrated circuit die formed in the semiconductor wafer.

FIG. 2C is a diagrammatic view of a semiconductor wafer 220, which may be the semiconductor wafer 22 of FIGS. 1A and 1B. The view of FIG. 2C may be a diagram of an image generated by a metrology tool that analyzes the semiconductor wafer 220. During exposure, in which light carrying the pattern of the mask patterns 230 is incident on the semiconductor wafer 220, the particle 250 alters the pattern, which is transferred repeatedly onto the semiconductor wafer 220. As such, quality of the semiconductor wafer 220 is reduced, reducing productivity of the lithography scanner.

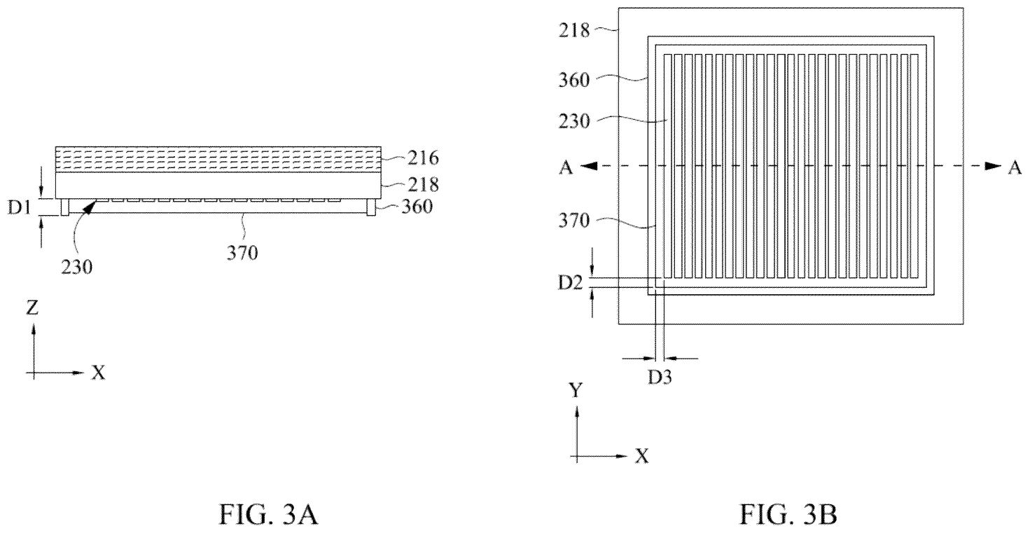

To prevent particles 250 from attaching to the mask patterns 230, a pellicle may be included that blocks the particles 250. FIGS. 3A and 3B depict a pellicle 370 that is attached to the mask assembly 200, and description thereof is provided as context for understanding the embodiments of the present disclosure. Generally, when the pellicle 370 is attached (e.g., mounted) to the mask assembly 200 as depicted in FIGS. 3A and 3B, the pellicle 370 experiences the same high acceleration forces as the mask assembly 200 along the X- and Y-axis directions due to rapid motion of the mask assembly 200. Namely, a first rate of acceleration of the mask assembly 200 (or the mask 218) is the same as a second rate of acceleration of the pellicle 370. For example, during scanning, the mask assembly 200 may move the mask patterns 230 smoothly across a narrow slit of EUV light while the wafer stage moves the wafer in an opposing direction, so as to expose the wafer to the entirety of the mask patterns 230. When finished, the mask assembly 200 may rapidly decelerate and/or change direction in the orthogonal direction in the horizontal plane. The mask assembly 200 may experience acceleration at a level of 15G, 20G or more. The pellicle 370 may also experience the same acceleration at a level of 15G, 20G or more. As such, the pellicle 370 may rupture easily due to its thin thickness.

FIGS. 3A and 3B are diagrammatic views showing a pellicle 370 and offset structure 360 installed on the mask assembly 200 to prevent the particles 250 from attaching to the mask 218. In FIGS. 3A and 3B, the pellicle 370 is shown suspended by the offset structure 360 over the mask patterns 230. The pellicle 370 may be a nanoscale thickness thin film that has high transparency (e.g., >90%) to EUV wavelengths (e.g., 13.5 nm). For example, the pellicle 370 may have thickness in the Z-axis direction in a range of about 50 nm to about 200 nm.

The offset structure 360 has height D1, which may be in a range of about 1 millimeter to about 3 millimeters, or more. The height D1 is about the same as a separation distance between the pellicle 370 and the mask patterns 230 in the Z-axis direction. The offset structure 360 may have rectangular (e.g., square) shape in the XY-plane, as shown in FIG. 3B. The offset structure 360 may be adjacent to the mask patterns 230 on four sides, as shown. The offset structure 360 may be offset horizontally in the X-axis and Y-axis directions from the mask patterns 230. For example, the offset structure 360 may be offset from the mask patterns by a second distance D2 in the Y-axis direction and by a third distance D3 in the X-axis direction. The distances D1, D2, D3 may be the same as each other. In some embodiments, one or more of the distances D1-D3 is different from others of the distances D1-D3. For example, the distance D1 may be in the range of about 1-3 millimeters as described above, and the second and third distances D2, D3 may be in a range of about 0.5 millimeters to about 10 millimeters. Mounting the pellicle 370 on the offset structure 360 can prevent mask defects formed by particles released by the lithography scanner. Generally, the distance D1 is sufficiently large such that any particle 250 less than a selected size (e.g., diameter less than about 500 nm) that settles on the outside surface of the pellicle 370 is far enough from a focus plane of incident light that the particle 250 does not cause a pattern defect.

The pellicle 370 may be operated for a selected number of wafers before being replaced. For example, the pellicle 370 may be said to have a “lifetime” of about 10,000 wafers, about 15,000 wafers, or the like. During manufacture of integrated circuit dies on the semiconductor wafer 220, the mask assembly 200 may translate back and forth along the XY plane, and particles may attach to the outside surface of the pellicle 370. The particles may include tool particles and pod particles, among other particle types described above with reference to FIGS. 2A-2C. Over time, as the particles accumulate on the pellicle 370, and due to repeated acceleration along the XY plane of the pellicle 370, the pellicle 370 may deform. Eventually, the pellicle 370 may rupture and is replaced.

When the pellicle 370 is mounted to the mask assembly 200 as depicted in FIGS. 3A and 3B, the pellicle 370 is subject to high acceleration forces due to rapid motion of the mask assembly 200 along the X- and Y-axis directions as described previously. As such, the pellicle 370 may rupture easily due to its thin thickness.

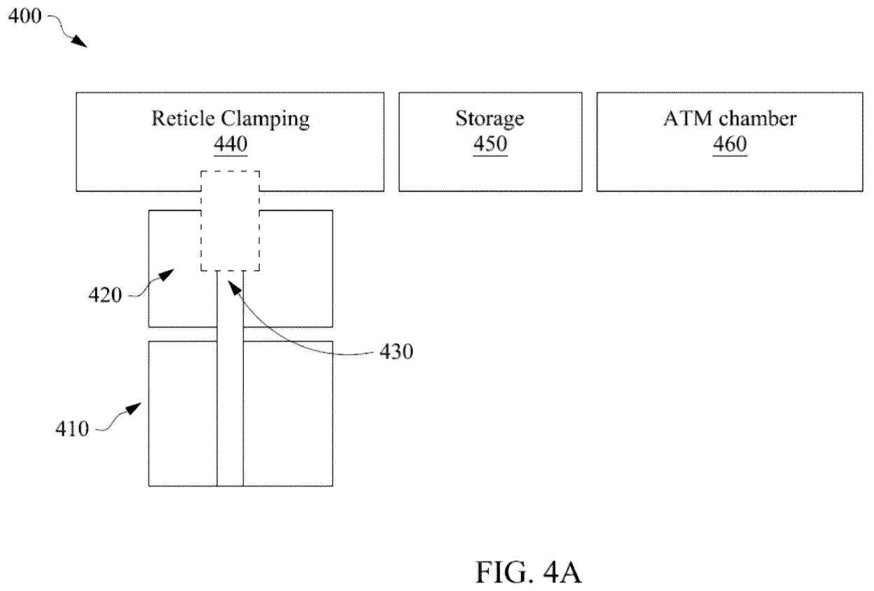

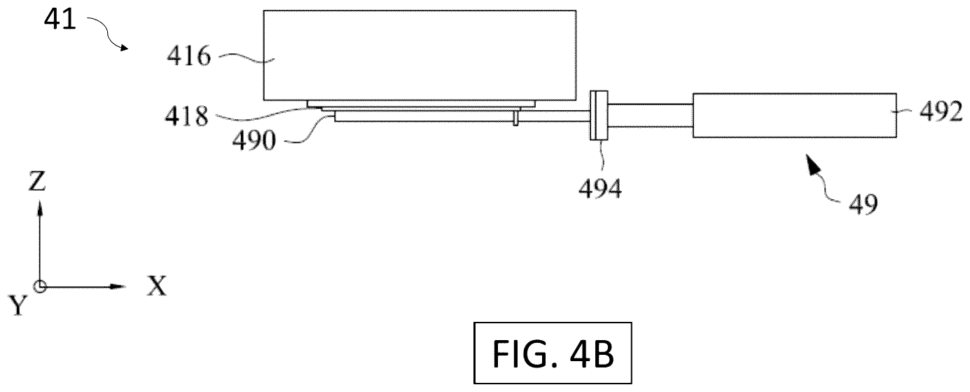

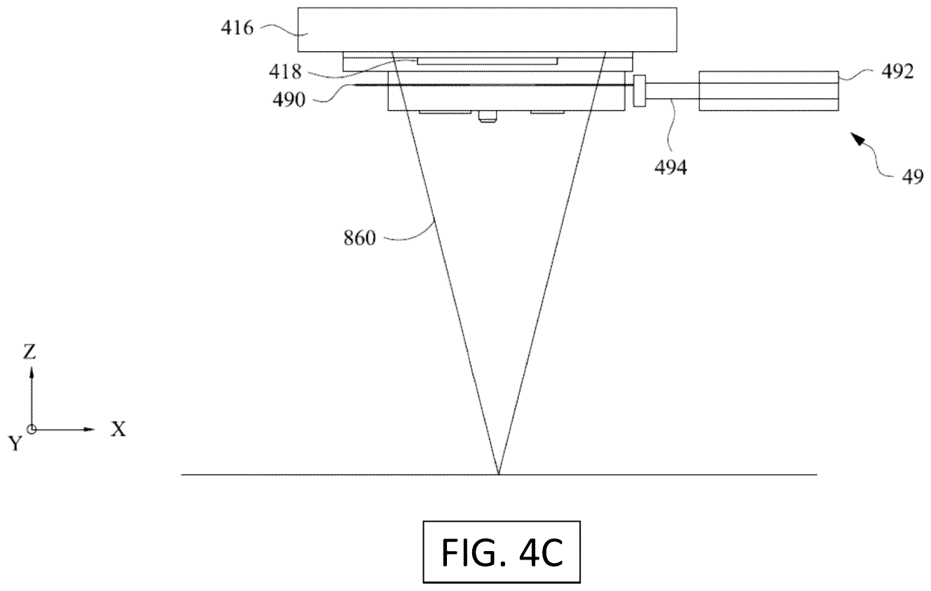

FIGS. 4A-4C are diagrams illustrating a partial structure of a lithography system 400 in accordance with various embodiments. In the embodiments, motion of a pellicle 490 is decoupled either completely or partially from motion of a mask stage 416, which is beneficial to reduce acceleration forces experienced by the pellicle 490 and thereby extend lifespan of the pellicle 490.

Another benefit is that the pellicle 490 may be formed with a thinner thickness, which may improve wafer throughput of a scanner that includes the pellicle 490 due to less power loss through the pellicle 490.

Decoupling the pellicle 490 from the mask stage 416 provides a further benefit that rework time may be decreased. This is because, instead of having to perform a complex process to remove (e.g., demount and remount) the pellicle 490 from the mask stage 416, the pellicle 490 may be easily discarded and replaced with a new pellicle simply by motion of, for example, a robot arm.

Another benefit is that acceleration of the mask stage 416 may be increased due to the acceleration not being applied to the pellicle 490.

Glue or adhesive selection for mounting the pellicle may also be more varied, which may eliminate use of specialized adhesives that are costly, hard to produce or have limited supply.

Another benefit is that instead of using one pellicle per mask in a semiconductor fab, one pellicle may be provided for each tool, which is beneficial to efficient pellicle usage and stocking. For example, number of pellicles used may decrease from about 200 pieces to about 6 pieces.

A pellicle swapping system including an atmosphere-vacuum interface chamber, turbo pump, and two sets of load-lock gate valves for vacuum-side and atmosphere-side is also provided. This is beneficial to improve flexibility to select application of a pellicle or not via recipe. For example, a higher power output of the EUV light may be paired with a thicker or higher-quality pellicle. In another example, higher power EUV light may be paired with faster scan speed of the mask assembly during exposure.

As another benefit, a vacuum system may be provided in communication with a pellicle handler to exhaust debris when facing rupture of the pellicle.

FIGS. 4A-4C depict a system 400 in accordance with various embodiments. FIG. 4A is a diagrammatic block diagram of the system 400. FIG. 4B is a side view diagram of the system 400. FIG. 4C is a further side view diagram of the system 400 illustrating an operation thereof.

The system 400 may include a first chamber or “swapping chamber” 410, a first transfer chamber or “first lock and load chamber” or “pellicle lock and load chamber” 420, a pellicle handler 430, a second chamber or “reticle clamping chamber” 440, a storage 450, a third chamber 460 and a second transfer chamber or “second lock and load chamber” or “mask lock and load chamber.”

The first chamber 410 may be a chamber that is at atmospheric pressure and may store one or more pellicles 490. A first transfer assembly or “first robot arm” may be positioned in the first chamber 410. The first robot arm may be operable to pick a pellicle 490 and move the pellicle 490 to an interface with the pellicle lock and load chamber 420.

The second chamber 440 may be a chamber that is at vacuum or near-vacuum pressure. A reticle stage or mask stage 416 may be positioned in the second chamber 440. A second transfer assembly may be positioned in the second chamber 440. The second transfer assembly may be operable to move the mask stage 416. For example, the mask stage 416 may be moved by the second transfer assembly during EUV scanning and/or during mounting of a mask 418 thereto. Exposure by EUV light scanning may be performed while the mask stage 416 and optionally the pellicle 490 are positioned in the second chamber 440.

The third chamber 460 may be a chamber that is at atmospheric pressure and may store one or more masks 418 (depicted in FIGS. 4B and 4C) or be in communication with the storage 450 that stores the one or more masks 418. In some embodiments, the storage 450 is included in the third chamber 460. A third transfer assembly or “second robot arm” may be positioned in the third chamber 460. The second robot arm may be operable to pick a mask 418 and move the mask 418 to an interface with the mask lock and load chamber for mounting the mask 418 to the mask stage 416.

The system 400 includes two lock and load chambers and may include at least one pump. The pump is in communication with the pellicle lock and load chamber 420. The lock and load chambers are beneficial to pressurize the pellicle 490 and the mask 418, respectively, during transfer between the second chamber 440 and the first chamber 410 and between the second chamber 440 and the third chamber 460, respectively. A fourth transfer assembly may be positioned in the pellicle lock and load chamber 420. The fourth transfer assembly is operable to pick the pellicle 490 from the first robot arm and to place the pellicle 490 on the pellicle handler 430. A fifth transfer assembly may be positioned in the mask lock and load chamber. The fifth transfer assembly is operable to pick the mask 418 from the second robot arm and transfer the mask 418 to the mask stage 416.

The pellicle 490 may be stored in the first chamber 410 at atmospheric pressure and the second chamber 440 may be at vacuum or near-vacuum pressure. When transferring the pellicle 490 from the first chamber 410 to the second chamber 440, the pellicle lock and load chamber 420 may initially be at atmospheric pressure or another pressure that matches pressure inside the first chamber 410. Once the pellicle 490 is positioned inside the pellicle lock and load chamber 420, the pump may pull down pressure in the pellicle lock and load chamber 420 to a pressure that matches pressure inside the second chamber 440 (e.g., vacuum or near-vacuum). The pellicle 490 may then be transferred to the second chamber 440 from the pellicle lock and load chamber 420.

The mask 418 may be stored in the third chamber 460 at atmospheric pressure and the second chamber 440 may be at vacuum or near-vacuum pressure. When transferring the mask 418 from the third chamber 460 to the second chamber 440, the mask lock and load chamber may initially be at atmospheric pressure or another pressure that matches pressure inside the third chamber 460. Once the mask 418 is positioned inside the mask lock and load chamber, a pump (not shown) may pull down pressure in the mask lock and load chamber to a pressure that matches pressure inside the second chamber 420 (e.g., vacuum or near-vacuum). The mask 418 may then be transferred to the second chamber 440 from the mask lock and load chamber.

FIG. 4B is a side view diagram depicting the mask assembly 41 and the pellicle assembly 49 in accordance with various embodiments. The pellicle assembly 49 may be an embodiment of the pellicle handler 430, and holds the pellicle 490 and is operable to translate the pellicle 490 in at least one horizontal direction (e.g., an X-axis direction depicted in FIG. 4D), independent of the mask assembly 41. The mask assembly 41 includes the mask stage 416 and the mask 418, and is operable to translate in the first direction independent of the pellicle 490. In some embodiments, the mask assembly 41 is operable to translate in two directions, such as the first direction (e.g., the X-axis direction of FIG. 4D) and a second direction (e.g., Y-axis direction of FIG. 4D) that is transverse (e.g., orthogonal to) the first direction. The second direction may be a horizontal direction, whereas the pellicle assembly 49 may be offset from the mask assembly 41 along a vertical direction, such as a Z-axis direction depicted in FIG. 4D. The mask stage 416 may be similar to the mask stage 16 described with reference to FIG. 1A. The mask 418 may be similar to the mask 18 described with reference to FIG. 1A. The pellicle 490 may be similar to the pellicle 370 described with reference to FIG. 3A.

The pellicle assembly 49 includes an actuator, which may be a linear actuator. The actuator includes a housing 492 and one or more rods 494 that are operable to move in and out of the housing 492 to provide motion along a single axis. In some embodiments, the actuator is a multidirectional actuator that provides motion along two or more axes, such as an XY linear stage actuator, gantry actuator or the like. The pellicle 490 is connected to the rods 494 and may be positioned based on extension and contraction of the rods 494. Control of extension and contraction of the rods 494 may be mechanical/electro mechanical, hydraulic, pneumatic, piezoelectric or the like. While not depicted, one or more of a screw (e.g., a ballscrew), spring, belt, motor or the like may be positioned in the housing 492 to provide control of extension and contraction of the rods 494.

The pellicle 490 may be offset from the mask 418 in the vertical Z-axis direction by a distance that is in a range of about 1 mm to about 10 mm, such as about 1 mm to about 3 mm. The pellicle 490 may have dimensions (e.g., width and length) in the first and second directions of about 1 cm×10 cm to about 30 cm×30 cm. In some embodiments, the mask 418 has a field size that is less than about 26 mm×33 mm or less than about 26 mm×16.5 mm. The pellicle 490 may have dimensions the same as those of the field size or larger. For example, the mask 418 may have a length in the X-axis direction of 33 mm, such that the mask assembly 41 may traverse a distance of about 66 mm for each scan of the mask 418. The pellicle 490 may have length the same as the distance over which the mask 418 traverses (e.g., about 66 mm) or longer. In some embodiments, the length of the pellicle 490 is between the length of the field size of the mask 418 and about twice the length of the field size of the mask 418. The length of the pellicle 490 being about the same as the field size may mean that the pellicle 490 shifts at about the same rate or acceleration as the mask 418 during scanning. The length of the pellicle 490 exceeding twice that of the field size may mean that the pellicle 490 shifts very little during scanning, but other difficulties such as warpage of the pellicle 490 may be more pronounced with larger area of the pellicle 490. Width of the pellicle 490 may be about the same as width of the field size of the mask 418 or even slightly larger to allow for reduced shifting of the pellicle 490 in the Y-axis direction.

In accordance with various embodiments, the pellicle 490 may be attached or mounted to a frame, which may be attached or mounted to an extension plate of the pellicle assembly 49. The extension plate may be attached to a rod plate, which is attached to the rods 494. The extension plate is offset from the rod plate along the first direction. The frame may attach to the extension plate by a fastener (e.g., one or more screws), one or more magnets, by sliding into a slot of the extension plate or in another appropriate manner. The frame may hold the pellicle 490 and may optionally stretch the pellicle 490 such that the pellicle 490 is taut.

FIG. 4C is another side view of the pellicle assembly 49 and the mask assembly 41 during scanning by light 860, in accordance with various embodiments. The light 860 may be similar to the light 86 described with reference to FIG. 1A. The light 860 may impinge on the mask 418 through the pellicle 490 held by the pellicle assembly 49. Although the light 860 is depicted as illuminating the entire mask 418, the light 860 may instead be a slit-shaped beam that illuminates a thin line of the mask 418, for example, along the Y-axis direction. The mask assembly 41 may move back and forth along the X-axis direction to reflect the light 860 from the entire surface of the mask 418. The pellicle 490 protects the mask 418 from particles, and may move independently of the mask assembly 41 due to not being mounted to the mask assembly 41.

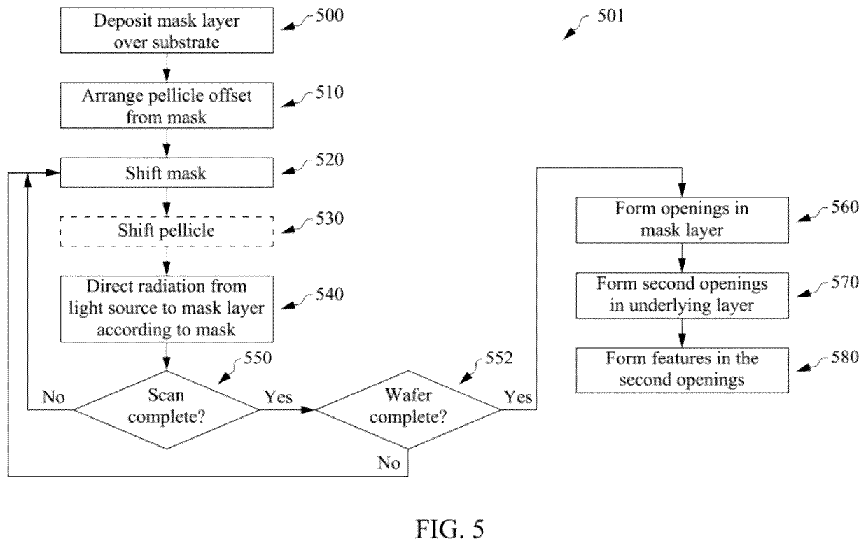

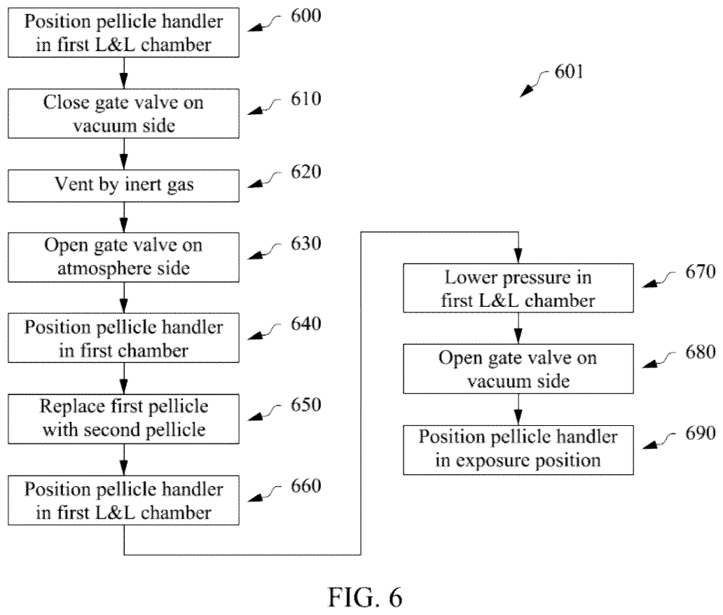

FIG. 5 is a flowchart of a process 501 for forming a device in accordance with various embodiments. In some embodiments, the process 501 for forming the device includes a number of operations (500, 510, 520, 530, 540, 550, 560, 570 and 580). FIG. 6 is a flowchart of a process 601 for replacing a pellicle in accordance with various embodiments. In some embodiments, the process 601 includes a number of operations (600, 610, 620, 630, 640, 650, 660, 670, 680 and 690). The processes 501, 601 will be further described according to one or more embodiments. It should be noted that the operations of the processes 501, 601 may be rearranged or otherwise modified from what is depicted in FIGS. 5 and 6 within the scope of the various aspects. It should further be noted that additional processes may be provided before, during, and after the processes 501, 601 and that some other processes may be only briefly described herein. In some embodiments, the processes 501, 601 are performed by the lithography exposure system 10 described in FIGS. 1A-4C. The embodiments are described with reference to the structural elements described in FIGS. 1A-4C, but the processes 501, 601 may be performed by a lithography system having one or more structural elements that are different from those of the lithography system 10. Some of the operations of the processes 501, 601 may be performed or controlled by the controller 90 described with reference to FIG. 1A.

In operation 500, a mask layer (e.g., a mask layer 26 shown in FIG. 1A) is deposited over a substrate. In some embodiments, the mask layer 26 includes a photoresist layer that is sensitive to the EUV radiation reflected by the mask 418. In some embodiments, the substrate is a semiconductor substrate, such as the semiconductor wafer 22 described with reference to FIGS. 1A and 1B. In some embodiments, the substrate is a layer overlying the semiconductor substrate, such as a dielectric layer, a metal layer, a hard mask layer, or other suitable layer. In some embodiments, the mask layer is deposited by spin coating or other suitable process.

In operation 510, a pellicle (e.g., the pellicle 490) is arranged offset from a mask (e.g., the mask 418). The pellicle 490 may be offset from the mask 418 in the Z-axis direction, as depicted in FIG. 4B. The pellicle 490 may overlap the mask 418 in the XY plane, for example. In operation 510, the pellicle 490 is not attached to the mask assembly 41 and is operable to move independent of motion of the mask assembly 41. This is described with reference to FIGS. 4A-4C above. Operation 510 may follow operation 500, in some embodiments. In other embodiments, operation 510 may be performed prior to or simultaneously with operation 500.

In operation 520, following arranging of the pellicle 490, the mask assembly 41 is translated so as to expose a region of the mask layer 26 on the substrate. For example, the mask assembly 41 may be translated in the X-axis direction, the Y-axis direction, or both. During translation of the mask assembly 400, the mask 418 thereof is protected by the pellicle 490. The mask 418 may be protected from particles by the pellicle 490. The protection may include deflecting one or more of the particles, adhering one or more of the particles, or both. The adhering may be physical by the pellicle 490 itself.

In optional operation 530, the pellicle 490 is shifted. For example, the pellicle 490 may be shifted along the X-axis direction, as depicted in FIG. 4D. In some embodiments, when the pellicle 490 is sufficiently large to cover the entirety of a translation path of the mask 418, the pellicle 490 may be stationary through the shifting of the mask 418 during scanning. When the pellicle 490 is shifted, the pellicle 490 may be shifted at a lower acceleration or a lower force than the mask 418. This is because the pellicle 490 is decoupled from the mask 418. In some embodiments, the pellicle 490 does not shift while the mask 418 shifts, such that the pellicle 490 experiences no force along the XY plane, e.g., the plane of motion of the mask 418. Shifting the pellicle 490 with reduced or no acceleration or force in the XY plane is beneficial for the reasons described above with reference to FIGS. 4A-4C.

In operation 540, radiation is reflected from the collector 60 and directed toward the mask layer 26. The radiation is reflected along an optical path between the collector 60 and the mask layer 26, which may be on the semiconductor wafer 22, such as that illustrated in FIG. 1A. In some embodiments, the radiation is reflected according to a pattern, such as exists on the mask 418, which may be a reflective mask. The radiation may be EUV light having wavelength centered at about 13.5 nm. The radiation may pass through the pellicle 490 before reaching the mask 418. In some embodiments, operation 540 is performed continuously while operation 520 and optional operation 530 are repeated throughout the scan.

In operation 550, in response to scanning being completed, e.g., if the entire pattern of the mask 418 has been transferred to the mask layer 26, the process 501 proceeds to operation 552. If less than then entire pattern of the mask 418 has been scanned, such that the scan is not complete, the process 501 proceeds to operation 520 to translate the mask 418.

In operation 552, a determination is made whether the entire wafer has been exposed. In response to the wafer being incomplete (e.g., one or more dies or die regions are still unexposed), the wafer stage may translate the wafer to a subsequent die or die region, and the process 501 may proceed to operation 520.

In operation 552, in response to the wafer being complete (e.g., all dies or die regions have been exposed), the process 501 may proceed to operation 560.

In operation 560, openings are formed in the mask layer 26 by removing pattern regions of the mask layer 26 exposed to the radiation. In some embodiments, the openings are formed by removing regions of the mask layer 26 not exposed to the radiation.

In operation 570, material of one or more layers underlying the mask layer 26 is removed, forming second openings. The material removed is in regions of the layer exposed by the openings in the mask layer 26. In some embodiments, the layer is a dielectric layer, a semiconductor layer, or other layer.

In operation 580, features are formed in the second openings of the layer. For example, source/drain regions may be epitaxially grown in the second openings. For example, metal traces may be deposited in the second openings. For example, gate structures including a high-k dielectric layer and a metal layer may be formed in the second openings.

FIG. 6 depicts a flowchart of a process 601 for replacing a pellicle (e.g., the pellicle 490) in accordance with various embodiments. In some embodiments, the pellicle 490 may be replaced under a number of different conditions. For example, the pellicle 490 may be replaced based on a lifetime of the pellicle 490 expiring. The pellicle 490 may be replaced based on the pellicle 490 being damaged or ruptured. The pellicle 490 may be replaced based on changing from one mask to another different mask. For example, a thinner or thicker pellicle may be used for either of the two masks. The pellicle 490 may be replaced based on a change in recipe. For example, a first exposure power may be used when scanning a first wafer, then a second exposure power may be used when scanning a second wafer. The pellicle 490 may be changed to a thicker or thinner pellicle based on using the first exposure power or the second exposure power. The pellicle 490 may be changed or removed based on a mask not needing protection of a pellicle. The process 601 may be performed by the lithography systems 10, 400 described with reference to FIGS. 1A-4C, but may also be performed by a similar lithography system that has fewer, more or different components than the lithography systems 10, 400.

In operation 600, when the pellicle 490 is to be changed or removed, the pellicle handler (e.g., the pellicle assembly 49) is positioned in a first lock and load chamber (e.g., the pellicle lock and load chamber 420). In some embodiments, the frame holding the pellicle 490 is picked by the fourth transfer assembly and moved into the pellicle lock and load chamber 420. In some embodiments, the entire pellicle assembly 49 with the pellicle 490 attached thereto is picked and moved into the pellicle lock and load chamber 420.

Operation 610 follows operation 600. In operation 610, following positioning the pellicle handler in the first lock and load chamber, a first gate valve on a vacuum side (e.g., a side connected to the second chamber 440) is closed. At this time, a second gate valve on an atmosphere side (e.g., a side connected to the first chamber 410) is also closed.

Operation 620 follows operation 610. In operation 620, following closing the first gate valve on the vacuum side, venting by inert gas may be performed. The venting may remove particles that have settled on the pellicle 490 and/or the pellicle handler 49 and may also bring pressure in the first lock and load chamber to a level similar to or the same as that of the first chamber. Operation 620 may be performed by the pump 66.

Operation 630 follows operation 620. In operation 630, following venting the first lock and load chamber, the second gate valve on the atmosphere side (e.g., that connects the first lock and load chamber 420 to the first chamber 410) is opened. During operation 630, the first gate valve remains closed.

Operation 640 follows operation 630. In operation 640, following opening the second gate valve on the atmosphere side, the pellicle handler is positioned in the first chamber. In some embodiments, the frame is moved from the pellicle lock and load chamber 420 to the first chamber 410 by the fourth transfer assembly. The first transfer assembly may pick the frame from the fourth transfer assembly. In some embodiments, the pellicle assembly 49 with the pellicle 490 attached thereto is moved from the first lock and load chamber 420 to the first chamber 410 by the fourth transfer assembly.

Operation 650 follows operation 640. In operation 650, following operation 640, the first pellicle is replaced with a second pellicle (or optionally with no pellicle). For example, the pellicle 490 (or “first pellicle”) in the frame may be removed from the pellicle assembly 49 and placed in storage or discarded, and another pellicle (or “second pellicle”) in another frame may be picked from storage by the first transfer assembly. Then, the second pellicle may be positioned on the pellicle assembly 49 by the first transfer assembly. The second pellicle may be the same as the pellicle 490, e.g., the second pellicle may have the same or similar parameters (length, width, thickness, material or the like) as the pellicle 490. For example, when the pellicle 490 is damaged or expires and is to be replaced, the second pellicle may be substantially the same as the pellicle 490. In some embodiments, the second pellicle is different from the pellicle 490. For example, when the lithography system begins a different batch of wafers under a different recipe, the second pellicle may have one or more parameters (e.g., length, width, thickness, material or the like) that are different from those of the pellicle 490. In some embodiments, the pellicle 490 is replaced with nothing. Namely, the lithography system may begin a batch of wafers for which the recipe does not call for a pellicle. As such, after storing or disposing of the pellicle 490, one or both of the first and fourth transfer assemblies may operate in a standby mode, waiting for instruction to pick yet another pellicle in a subsequent operation. For example, the pellicle assembly 49 may be positioned in the first chamber 410 while a wafer is being exposed using a mask with no pellicle therebetween.

Operation 660 follows operation 650. Following replacement of the first pellicle 490 with the second pellicle, the pellicle handler (e.g., the pellicle assembly 49) having the second pellicle attached thereto is positioned in the first lock and load chamber (e.g., the first lock and load chamber 420). In some embodiments, the pellicle assembly 49 is picked by the fourth transfer assembly from the first transfer assembly, and the fourth transfer assembly retracts to position the pellicle assembly 49 inside the first lock and load chamber 420. At this time, a door or gate valve that connects the first lock and load chamber 420 to the second chamber 440 may be closed.

Operation 670 follows operation 660. After the pellicle assembly 49 having the second pellicle attached thereto is positioned in the first lock and load chamber 420, pressure in the first lock and load chamber 420 is lowered. In some embodiments, the pressure in the first lock and load chamber 420 is lowered to pressure level that is at vacuum or near-vacuum. The pressure in the first lock and load chamber 420 may be lowered to a pressure level that is the same as or about the same as that of the second chamber 440. When the pressure of the second chamber 440 is at vacuum or near-vacuum, the pressure of the first lock and load chamber 420 may be lowered to vacuum or near-vacuum, respectively in operation 670. This is beneficial to avoid damage to the second pellicle during transfer of the second pellicle to the second chamber 440. Pumping down the pressure may also be beneficial to remove particles that may be present on the second pellicle prior to using the second pellicle during exposure. Prior to drawing down the pressure in the first lock and load chamber 420, a door or gate valve that connects the first lock and load chamber 420 to the first chamber 410 may be closed. Operation 670 may be performed by the pump 66.

Operation 680 follows operation 670. After the pressure of the first lock and load chamber 420 is lowered to at or near that of the second chamber 440, the gate valve that connects the first lock and load chamber 420 and the second chamber 440 is opened.

Operation 690 follows operation 680. After the gate valve is opened, the pellicle handler (e.g., the pellicle assembly 49 with the second pellicle attached thereto) may be positioned in an exposure position. The exposure position may be in the second chamber 440. The pellicle assembly 49 may be attached to a housing of the second chamber 440, or may be held in place by another assembly in the second chamber 440 that is attached to the housing. The exposure position may be a position selected such that the second pellicle overlaps a mask that the second pellicle is to protect during exposure of a wafer.

With the second pellicle in the exposure position, an exposure operation may be performed to transfer a pattern of a mask protected by the second pellicle to a layer (e.g., a resist layer) of a semiconductor wafer.

Embodiments may provide advantages. The pellicle 490 being decoupled from the mask 418 improves reliability and lifetime of the pellicle 490 due to the pellicle 490 experiencing lower or no force or acceleration compared to the mask 418. The pellicle 490 being held by the pellicle handler or pellicle assembly 49 allows for a single pellicle 490 to be used with multiple masks 418, improving efficiency of use of pellicles 490 in the lithography exposure system 10. The pellicle assembly 49 may reduce rework and allow for rapid discarding and replacement when the pellicle 490 is at its end of life, is damaged or is ruptured.

In accordance with at least one embodiment, a method includes: depositing a mask layer over a substrate; protecting a mask of a mask assembly by a pellicle attached to a pellicle assembly, the pellicle and the pellicle assembly being laterally offset from the mask assembly by a distance; directing first radiation toward the mask with the pellicle positioned overlapping the mask; and exposing the mask layer of a semiconductor wafer by second radiation carrying a pattern of the mask.

In accordance with at least one embodiment, a method includes: exposing a first semiconductor wafer by performing a first exposure operation using a first mask and a first pellicle, the first pellicle being attached to a pellicle assembly, the first pellicle and the pellicle assembly being laterally offset from the first mask by a distance, the pellicle assembly including an actuator; removing the first pellicle from the pellicle assembly; after the removing, attaching a second pellicle to the pellicle assembly, the second pellicle being a different pellicle than the first pellicle; and exposing a second semiconductor wafer by performing a second exposure operation using the second pellicle.

In accordance with at least one embodiment, a method includes: a light source that, in operation, generates light; a mask having a pattern, the mask, in operation, reflecting the light according to the pattern; a pellicle that is offset from the mask and is between the mask and the light source; and a pellicle assembly that, in operation, moves the pellicle with first motion that is independent of second motion of the mask.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
depositing a mask layer over a substrate;
protecting a mask of a mask assembly by a pellicle attached to a pellicle assembly, the pellicle and the pellicle assembly being laterally offset from the mask assembly by a distance;
directing first radiation toward the mask with the pellicle positioned overlapping the mask; and
exposing the mask layer of a semiconductor wafer by second radiation carrying a pattern of the mask.

2. The method of claim 1, further comprising:
moving the mask; and
moving the pellicle by the pellicle assembly while the mask is moving, motion of the pellicle being independent of motion of the mask.

3. The method of claim 1, further comprising:
accelerating the mask at a first rate; and
accelerating the pellicle during the accelerating the mask, the accelerating the pellicle being at a second rate that is different than the first rate.

4. The method of claim 3, wherein the accelerating the pellicle at a second rate is accelerating the pellicle at the second rate that is less than the first rate.

5. The method of claim 1, further comprising:
moving the mask; and
during the moving the mask, holding the pellicle stationary.

6. The method of claim 1, further comprising:
during the exposing the mask layer, moving the pellicle by an actuator of the pellicle assembly.

7. The method of claim 1, further comprising:
forming a first opening in the mask layer by removing a pattern region of the mask layer based on the pattern;
forming a second opening by removing at least a portion of a layer underlying the mask layer exposed by the first opening; and
forming a feature of a semiconductor device in the second opening.

8. A method, comprising:
exposing a first semiconductor wafer by performing a first exposure operation using a first mask and a first pellicle, the first pellicle being attached to a pellicle assembly, the first pellicle and the pellicle assembly being laterally offset from the first mask by a distance, the pellicle assembly including an actuator;
removing the first pellicle from the pellicle assembly;
after the removing, attaching a second pellicle to the pellicle assembly, the second pellicle being a different pellicle than the first pellicle; and
exposing a second semiconductor wafer by performing a second exposure operation using the second pellicle.

9. The method of claim 8, wherein the exposing a second semiconductor wafer includes the performing a second exposure operation using a second mask different than the first mask.

10. The method of claim 8, further comprising:
prior to the removing the first pellicle, transferring the pellicle assembly and the first pellicle to a lock and load chamber.

11. The method of claim 10, further comprising:
cleaning the first pellicle by venting the lock and load chamber.

12. The method of claim 10, further comprising:
increasing a pressure in the lock and load chamber to a first level about atmospheric pressure.

13. The method of claim 12, further comprising:
after the increasing the pressure, transferring the pellicle assembly from the lock and load chamber to a first chamber.

14. The method of claim 10, further comprising:
after the attaching a second pellicle, moving the pellicle assembly from the first chamber to the lock and load chamber.

15. The method of claim 14, further comprising:
after the moving the pellicle assembly, lowering the pressure of the lock and load chamber to a second level that is at vacuum or near-vacuum; and
after the lowering pressure, moving the pellicle assembly to an exposure position in which the second pellicle is between a light source and the first mask.

16. A system, comprising:
a light source that, in operation, generates light;
a mask having a pattern, the mask, in operation, reflecting the light according to the pattern;
a pellicle that is offset from the mask and is between the mask and the light source; and
a pellicle assembly that, in operation, moves the pellicle with first motion that is independent of second motion of the mask.

17. The system of claim 16, wherein the pellicle assembly includes an actuator.

18. The system of claim 16, wherein the pellicle is offset from the mask by a distance in a range of about 1 millimeter to about 3 millimeters.

19. The system of claim 16, further comprising:
a second chamber that, in operation, is at a vacuum or near-vacuum pressure, the mask being in the second chamber during exposing a semiconductor wafer by the light reflected therefrom;
a first chamber that, in operation, is at a pressure higher than that of the second chamber; and
a lock and load chamber that, in operation:
is at the vacuum or near-vacuum pressure while the lock and load chamber receives the pellicle assembly and the pellicle from the second chamber; and
is at the pressure while the lock and load chamber transfers the pellicle assembly and the pellicle to the first chamber.

20. The system of claim 16, wherein the pellicle assembly is further operable to hold the pellicle stationary while the mask is moving.
